(19) United States
(12) Patent Application Publication
(10) Pub. No.: US 2016/0284890 A1
(43) Pub. Date: Sep. 29, 2016

(54) ANTIOXIDANT CONDUCTIVE COPPER INK AND METHOD FOR PREPARING THE SAME

(71) Applicant: INSTITUTE OF NUCLEAR ENERGY RESEARCH, ATOMIC ENERGY COUNCIL EXECUTIVE YUAN, R.O.C., Taoyuan County (TW)

(72) Inventors: WEI-CHEN CHANG, TAOYUAN COUNTY (TW); WEI-YANG MA, TAOYUAN COUNTY (TW); GUAN-LIN CHEN, TAOYUAN COUNTY (TW); LI-WEI WENG, TAOYUAN COUNTY (TW); CHENG-HUAN CHUNG, TAOYUAN COUNTY (TW); TSUN-NENG YANG, TAOYUAN COUNTY (TW); CHENG-SI TSAO, TAOYUAN COUNTY (TW); YU-CHING HUANG, TAOYUAN COUNTY (TW)

(21) Appl. No.: 14/705,062

(22) Filed: May 6, 2015

(30) Foreign Application Priority Data
Mar. 23, 2015 (TW) 104109246

(51) Int. Cl. H01L 31/0224; H05K 1/09; C09D 11/52

(52) U.S. Cl. CPC H01L 31/022425; C09D 11/52; H05K 1/092

(57) ABSTRACT

The present relates to antioxidant conductive copper ink and the method for preparing the same. The antioxidant conductive copper ink comprises nanometer copper or copper-alloy particles, which are used as the conductive particle material, water-free alcohol, which is used as the solvent, tert-butanol and ultra-pure water, which is used as the pasting agent, and carboxylic acid, which is used as the dispersant. Alternatively, isopropanol is used as the pasting agent and glycol is used as the solvent for injecting processes. The antioxidant conductive copper ink disclosed in the present invention owns the properties of high stability and low cost, and hence is applicable to the applications of fabricating the electrodes of silicon-crystal solar cells and printable electronic materials such as PCB or RFID.

### FIELD OF THE INVENTION

The present invention relates generally to copper ink and the method for preparing the same, and particularly to antioxidant conductive copper ink and the method for preparing the same applicable to fabricating the electrodes of silicon-crystal solar cells or the metal circuits of printable electronic devices.

### BACKGROUND OF THE INVENTION

The research of solar cells is a direction of renewable energy highly expected by people. No greenhouse-effect gas, including carbon dioxide, oxynitrides, and oxide sulfides, and pollutant gas will be generated during the power generating process. Instead, the photoelectric effect is used for converting the solar energy to electric energy and hence solar cells are endowed with the technical advantage of not consuming non-renewable resources. In the modern age of gradually exhausting resource and increasing energy price, they are highly valued.

Currently, in the fabrication technology for the electrodes of silicon-crystal solar cells, the ink is mainly composed by silver or other composite materials. The electrical conductivity of nanometer silver ink is excellent. Nonetheless, being a noble metal, the cost of silver is relatively higher. In addition, a higher temperature is required in the process for manufacturing nanometer silver particles; ion migration in the fabricated electrodes occurs easily. Accordingly, there is incentive to develop other nanometer metal particles for replacing nanometer silver ones.

In addition to solar cells, another application that uses conductive ink is printable electronic device, which is a field having a broad market. By combining the advantages of lightness and compact size of printable electronic devices and low cost and mass productivity of the printing technology, the related products, for example, PCB in electronic products or wireless smart tags such as REID, can be applied extensively in daily lives. Besides, the conductive ink is also applicable to printing on novel flexible electronic materials.

Having much lower cost than nanometer silver particles, nanometer copper particles are potential candidates. There are many methods for fabricating nanometer copper particles. In the early times, hydrazine reductants are adopted. Unfortunately, this process is toxic and dangerous. If sodium borohydride or sodium hydrophosphate is used as the reductants, impure materials that are difficult to purify are produced, or the synthesis must be performed in vacuum, which increases the cost. Consequently, various novel methods are developed gradually. For example, copper hydroxide is used as the precursor salt and L-ascorbic acid is used as the reductant. This wet chemical reduction method owns the advantage of avoiding toxic materials as well as further using polymeric protectors to keep the product from oxidation. Furthermore, the hydrothermal method can be adopted for preparing nanometer-silver-coated copper particles, which use nanometer copper particles as the center bodies coated with a silver layer of 2˜5 nanometers. Thereby, the amount of silver used is reduced while increasing the oxidation resistance of the nanometer copper particles.

When nanometer copper particles replace nanometer silver particles and are used as the material for conductive ink, specific solvent and dispersant are required for dispersing nanometer copper particles uniformly in the solvent and preventing aggregation of nanometer copper particles, which may lower the electrical conductivity of the nanometer copper particles. Besides, the solvent and dispersant also need to prevent oxidation of the nanometer copper particles. If the nanometer copper ink is oxidized, when the electrodes of silicon-crystal solar cells and printable electronic materials are formed by various methods, such as printing, coating, and screen printing, according to the prior art, the quality of the silicon-crystal solar cells and the printable electronic materials would be inferior. Even if oxidation occurs after the electrodes are formed, the rapid increase in the resistance of the electrodes will reduce severely the power generating efficiency of the silicon-crystal solar cells and affect the electrical conductivity of the printable electronic materials such as PCBs. Accordingly, it is required to provide a method for preparing conductive copper ink having oxidation resistance and superior dispersibility.

### SUMMARY

An objective of the present invention is to provide conductive copper ink having excellent oxidation resistance and dispersibility. It is difficult for the contained nanometer copper particles to form nanometer copper-oxide particles. Thereby, for the copper ink or the electrodes formed by printing, coating, and ink injecting processes, the conductive copper ink provides superior stability; the resistance will not increase apparently with time.

Another objective of the present invention is to provide antioxidant conductive copper ink, which is applicable to fabricating the electrodes of silicon-crystal solar cells. In particular, the width of silicon-crystal soar cells should be as narrow as possible in order to prevent lowering in the power generating efficiency of the solar cells caused by the shadow effect. In addition, the viscosity of the antioxidant copper ink disclosed in the present invention is above the criterion for maintaining a fixed thickness of the electrodes. Given the sufficient thickness of the electrodes, better conductivity is guaranteed.

Still another objective of the present invention is to provide antioxidant conductive copper ink, which is also applicable to the field of printable electronic devices, for example, the PCBs in electronic products or wireless smart tags such as RFIDs. In addition, the present invention is also applicable to being printed on various novel flexible electronic materials and used as a method for forming metal circuits rapidly.

A further objective of the present invention is to provide a method for preparing antioxidant conductive copper ink. The method includes specific steps and compositions for preparing antioxidant conductive copper ink having excellent oxidation resistance and uniform distribution of nanometer copper particles.

A still further objective of the present invention is to provide antioxidant conductive copper ink, which is formed by using different solvents and pasting agents and applicable to ink injecting processes. Thereby, the antioxidant conductive copper ink can be applied to fabricating fine circuits.

In order to achieve the above objectives, the present invention discloses antioxidant conductive copper ink and the method for preparing the same. The composition of the antioxidant conductive copper ink comprises a conductive particle material having a weight percentage of 20%˜40%, a solvent having a weight percentage of 40%˜55%. a pasting agent having a weight percentage of 20%˜25%, and a trace of dispersant having a weight percentage of less than 3%. The conductive particle material includes nanometer copper particles or nanometer copper-alloy particles. The solvent is water-free alcohol. The pasting agent is tert-butanol. The dispersant is carboxylic acid. The method for preparing comprises steps of mixing the conductive particle material, the solvent, and the pasting agent to form a mixed solution; oscillating the mixed solution using ultrasonic waves; and adding the carboxylic acid to the mixed solution for forming the antioxidant conductive copper ink.

According to another preferred embodiment of the present invention, the prepared antioxidant conductive copper ink comprises a conductive particle material having a weight percentage of 20%˜40%. a solvent having a weight percentage of 10%˜40%, a pasting agent having a weight percentage of 30%˜70%, and a dispersant having a weight percentage of less than 3%. The conductive particle material includes nanometer copper particles or nanometer copper-alloy particles. The solvent is glycol. The pasting agent is isopropanol. The dispersant is carboxylic acid. Since no tert-butanol, which has higher viscosity, is added, the antioxidant conductive copper ink is more suitable for ink injecting process, thanks to its property of not jamming the nozzle of ink cartridges.

### BRIEF DESCRIPTION OF THE DRAWINGS

FIG. 1 shows a flowchart of the method for preparing according to a preferred embodiment of the present invention; and

FIG. 2 shows a flowchart of the method for preparing according to another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The composition of the antioxidant conductive copper ink according to the present invention comprises a conductive particle material having a weight percentage of 20%˜40%, a solvent having a weight percentage of 40%˜55%, a pasting agent having a weight percentage of 20%˜25%, and a trace of dispersant having a weight percentage of less than 3%.

In the above composition, the adopted conductive particle material is nanometer copper particles or nanometer copper-alloy particles, which are cheaper than nanometer silver particles. According to the present invention, the electrical conductivity of copper is used as the electrodes of silicon-crystal solar cells and circuits of the printable electronic material. Thereby, the method for preparing or the purchasing source of the nanometer copper or copper-alloy particles is not limited; the properties of the finished product will not influence by the above condition, either. The diameter of the nanometer copper or copper-alloy particles adopted by the present invention is less than 500 nanometers.

The solvent adopted in the present invention is water-free alcohol with purity higher than 99.5%. The benefit of using water-free alcohol is reducing the water content in the solvent as much as possible for preventing forming copper oxide after mixing the conductive particle material, which is formed by oxidation-prone nanometer copper or copper-alloy particles, with the solvent. In addition, the ratio of the weight percentage of the conductive particle material to that of the solvent is preferably 1:2.

Because the viscosity of water-free alcohol is lower, as a user disposes it on the surface of a target using printing, coating, and injecting methods, the spread of the water-free alcohol cannot be controlled effectively. Consequently, it is not suitable to be used alone as the carrier of the conductive particle material in ink. According to the present invention, the pasting agent is used for improving the viscosity of the ink. According to the present preferred embodiment, tert-butanol is adopted as the pasting agent. Tert-butanol can be resolved in alcohol with a boiling point of approximately 82.4° C. A temperature lower than 100° C. can vaporize it, endowing it with the property of low-temperature sintering. The ratio of the solvent to the pasting agent should be adjusted before the conductive copper ink according to the present invention has appropriate viscosity. Accordingly, in the subsequent applications, products having slightly different viscosity can be provided according to the printing. costing, or spin coating methods or to the application environment.

The melting point of tert-butanol is only slightly higher than the room temperature, making it tend to be in the solid state and hard to be processed. Hence, according to a preferred embodiment, tert-butanol will be first revolved in the deionized water (super-pure water) with a preferable ratio in weight percentage of 2:1. According to the present preferred embodiment, the deionized water is adopted for resolving tert-butanol. Because the deionized water is in the pure-water state with various ions therein eliminated, the nanometer copper or copper-alloy particles will not be oxidized rapidly even the deionized water is first mixed with tert-butanol before added into the conductive copper ink as a part of the pasting agent. The oxidation resistance of the conductive particle material, the solvent, and the pasting agent after mixing is still maintained.

Another composition of the conductive copper ink is carboxylic acid added with a proper amount. Carboxylic acid is a solution containing carboxyl group. According to another preferred embodiment of the present invention, lactic acid is adopted. The purpose of the dispersant is to prevent aggregation of the nanometer copper or copper-alloy particles, which are used as the conductive particle material.

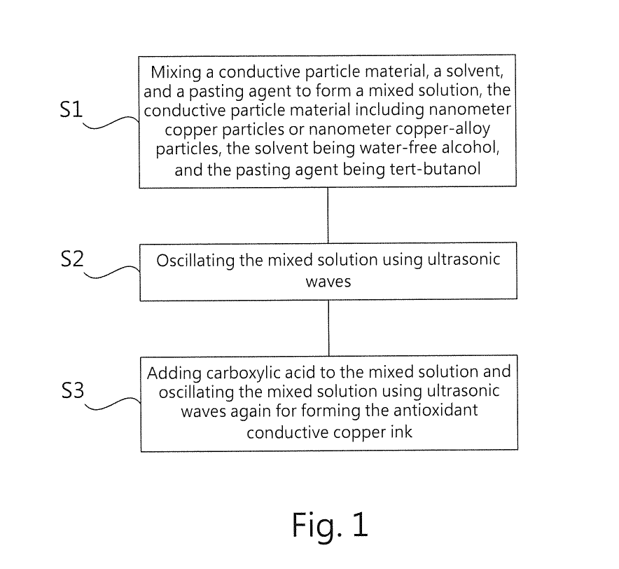

Please refer to FIG. 1. The method for preparing the antioxidant conductive copper ink according to the present invention comprises steps of:
Step S1: Mixing a conductive particle material, a solvent, and a pasting agent to form a mixed solution, the conductive particle material including nanometer copper particles or nanometer copper-alloy particles, the solvent being water-free alcohol, and the pasting agent being tert-butanol;
Step S2: Oscillating the mixed solution using ultrasonic waves; and
Step S3: Adding carboxylic acid to the mixed solution and oscillating the mixed solution using ultrasonic waves again for forming the antioxidant conductive copper ink.

In the above steps, the mixed materials are the nanometer copper or copper-alloy particles, the water-free alcohol, and the tert-butanol as described above. After mixing, ultrasonic waves are used first for 0.5 to one hour for mixing them uniformly. Then the carboxylic acid, which acts as the dispersant, is added. The ultrasonic-wave oscillation is continued for ensuring that the conductive particle materials will not aggregate.

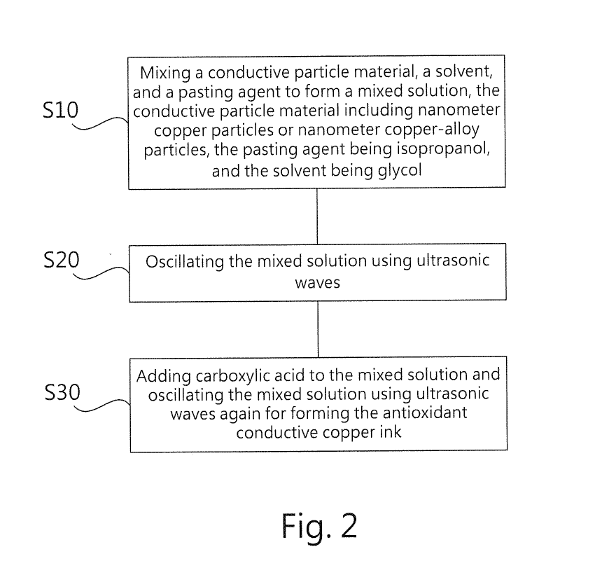

According to another preferred embodiment of the present invention, as the steps S10˜S30 shown in FIG. 2, isopropanol (IPA), whose viscosity is similar to maple syrup, is adopted as the pasting agent and glycol (EG) is adopted as the solvent. The ratio in weight between the two is around 1:1˜7:1 and preferably 5:1. After mixing the nanometer copper particles with the liquid formed by IPA and EG in a preferably 1:3 weight proportion, no tert-butanol, which acts as the pasting agent in the previous preferred embodiment, is added. Next, the mixture is oscillated using ultrasonic waves for around 0.5 to 1 hour. After fully mixed, carboxylic acid, which acts as the dispersant, is added. Then ultrasonic-wave oscillation is continued for ensuring that the conductive particle materials will not aggregate.

According to another preferred embodiment of the present invention, the prepared antioxidant conductive copper ink comprises a conductive particle material having a weight percentage of 20%˜40%, a solvent having a weight percentage of 10%˜40%, a pasting agent having a weight percentage of 30%˜70%, and a dispersant having a weight percentage of less than 3%. The characteristics of the antioxidant conductive copper ink are suitable for injecting processes. It adopts IPA, whose viscosity is lower, as the pasting agent. Thereby, less jamming problem will occur as compared to the antioxidant conductive copper ink prepared according to the previous preferred embodiment. Furthermore, the nozzle in the injecting processes is only approximately 20 micrometers, making the selection standard for the ink in the injecting processes substantially high. After preparing the antioxidant conductive copper ink according to the present preferred embodiment, the ink is packages in cartridges, which is then used in fabricating the electrode of silicon-crystal solar cells or the metal circuits of printable electronic devices.

The selection of conductive copper ink for fabricating the electrode of silicon-crystal solar cells or the metal circuits of printable electronic devices depends on the fabricated target. For example, to fabricate a large-area conductive region, the coating method using the conductive copper ink having higher viscosity is adopted. On the contrary, for fine circuits, the micro nozzle in the injecting process is adopted for disposing the jam-free conductive copper ink on the circuit boards. No matter which type of the conductive copper ink disclosed in the present invention is adopted, excellent oxidation resistance is exhibited.

After preparing the antioxidant conductive copper ink using the method disclosed in the present invention, electrodes can be manufactured by various methods according to the various processes for silicon-crystal solar cells or the required area. For example, for large areas, coating, scroll-type screen coating, and screen printing methods can be adopted for disposing the antioxidant conductive ink on the surface of the silicon-crystal solar cell structures for fabricating the electrodes. Alternatively, for small-area processes, spin coating can be adopted for fabrication. Moreover, the present invention is applicable to the field of printable electronic devices. For example, the copper ink is printed or injected to form the PCB or RFID in electronic products. No matter what kind of process is used, thanks to the property of the oxidation-resistance conductive copper ink according to the present invention of unlikeliness in forming copper oxide, the resistance of the ink or the formed electrodes can be maintained. The resistance will not increase apparently with time, which facilities lifetime and stability of the silicon-crystal solar cells and various printable electronic products. Having the benefits of low cost and performance, the present invention undoubtedly provides antioxidant conductive copper ink and the method for preparing the same with practical and economic values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. An antioxidant conductive copper ink, comprising:
a conductive particle material, having a weight percentage of 20%˜40%, and including nanometer copper particles or nanometer copper-alloy particles;
a solvent, having a weight percentage of 40%˜55%, and being water-free alcohol;
a pasting agent, having a weight percentage of 20%˜25%, and being tert-butanol; and
a dispersant, having a weight percentage of less than 3%, and being carboxylic acid.

2. The antioxidant conductive copper ink of claim 1, wherein said antioxidant conductive copper ink is used for fabricating the electrodes of silicon-crystal solar cells or the metal circuits of printable electronic devices.

3. The antioxidant conductive copper ink of claim 1, wherein the ratio of the weight percentage of said conductive particle material to the weight percentage of said solvent is 1:2.

4. The antioxidant conductive copper ink of claim 1, wherein said carboxylic acid is lactic acid.

5. The antioxidant conductive copper ink of claim 1, wherein the diameter of said nanometer copper particles or said nanometer copper-alloy particles is less than 500 nanometers.

6. A method for preparing antioxidant conductive copper ink, comprising steps of:
mixing a conductive particle material, a solvent, and a pasting agent to form a mixed solution, said conductive particle material including nanometer copper particles or nanometer copper-alloy particles, said solvent being water-free alcohol, and said pasting agent being tert-butanol;
oscillating said mixed solution using ultrasonic waves; and
adding carboxylic acid to said mixed solution for forming said antioxidant conductive copper ink.

7. The method for preparing antioxidant conductive copper ink of claim 6, wherein said pasting agent further comprises deionized water.

8. The method for preparing antioxidant conductive copper ink of claim 7, wherein the ratio of the weight percentage of said tert-butanol to the weight percentage of said deionized water is 2:1.

9. The method for preparing antioxidant conductive copper ink of claim 6, wherein the time for using ultrasonic waves is 0.5 to 1 hour.

10. An antioxidant conductive copper ink, comprising:
a conductive particle material, having a weight percentage of 20%˜40%, and including nanometer copper particles or nanometer copper-alloy particles;
a pasting agent, having a weight percentage of 30%˜70%, and being isopropanol;
a solvent, having a weight percentage of 10%˜40%, and being glycol; and
a dispersant, having a weight percentage of less than 3%, and being carboxylic acid.

11. The antioxidant conductive copper ink of claim 10, wherein said carboxylic acid is lactic acid.

12. The antioxidant conductive copper ink of claim 10, wherein the ratio of the weight percentage of said conductive particle material to the weight percentage of said solvent is 1:3.

13. A method for preparing antioxidant conductive copper ink, comprising steps of:
mixing a conductive particle material, a solvent, and a pasting agent to form a mixed solution, said conductive particle material including nanometer copper particles or nanometer copper-alloy particles, said pasting agent being isopropanol, and said solvent being glycol;
oscillating said mixed solution using ultrasonic waves; and
adding carboxylic acid to said mixed solution for forming said antioxidant conductive copper ink.

14. The method for preparing antioxidant conductive copper ink of claim 13, wherein after forming said antioxidant conductive copper ink, said antioxidant conductive copper ink is packaged in cartridges for fabricating the electrodes of silicon-crystal solar cells or the metal circuits of printable electronic devices using injecting process.
